(19) United States
(12) Patent Application Publication
(10) Pub. No.: US 2026/0282876 A1
(43) Pub. Date: Sep. 17, 2026

(54) INTERCONNECT STRUCTURE

(71) Applicant: TAIWAN SEMICONDUCTOR MANUFACTURING COMPANY, LTD., Hsinchu (TW)

(72) Inventors: Chia Chen LEE, Hsinchu (TW); Chia-Tien WU, Hsinchu (TW); Yi-Yi CHEN, Hsinchu (TW); Chi-Yu LU, Hsinchu (TW)

(73) Assignee: TAIWAN SEMICONDUCTOR MANUFACTURING COMPANY, LTD., Hsinchu (TW)

(21) Appl. No.: 19/081,690

(22) Filed: Mar. 17, 2025

(51) Int. Cl. H01L 23/528; H01L 21/768; H01L 23/522; H10D 84/83

(52) U.S. Cl. CPC H10W 20/427; H10W 20/056; H10W 20/42; H10W 20/435; H10D 84/83

(57) ABSTRACT

A interconnect structure is disposed on a device region along a first axis, and includes a first dielectric layer, a second dielectric layer adjacent to the first dielectric layer along the first axis, a plurality of first metal lines disposed in the first dielectric layer and extending along a second axis transverse to the first axis, and a plurality of second metal lines disposed in the second dielectric layer and extending along the second axis. The second axis corresponds to a lengthwise direction of the plurality of first metal lines, and a lengthwise direction of the plurality of second metal lines.

### BACKGROUND

The semiconductor integrated circuit (IC) industry has over the past decades experienced tremendous advancement and is still experiencing vigorous development. However, advances in IC design need to be accompanied by improvements in manufacturing in order to optimize device performance. As an example, interconnections between different layers of wires and associated dielectrics affect IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of an arrangement of metal lines with respect to a first metal line layer in accordance with some embodiments.

FIG. 2 is a sectional view taken along line A-A in FIG. 1 in accordance with some embodiments.

FIG. 3 is a top view of an arrangement of metal lines with respect to the first metal line layer and a second metal line layer in accordance with some embodiments.

FIG. 4 is a sectional view taken along line B-B in FIG. 3 in accordance with some embodiments.

FIG. 5 is a top view of an arrangement of metal lines with respect to the first metal line layer, the second metal line layer and a third metal line layer in accordance with some embodiments.

FIG. 6 is a sectional view taken along line C-C in FIG. 5 in accordance with some embodiments.

FIG. 7 is a top view illustrating a routing of metal lines in multiple layers in accordance with some embodiments.

FIG. 8 is a sectional view taken along line D-D in FIG. 7 in accordance with some embodiments.

FIG. 9 is a top view illustrating a routing of metal lines in multiple layers in accordance with some embodiments.

FIG. 10 is a sectional view taken along line E-E in FIG. 9 in accordance with some embodiments.

FIG. 11 is a top view illustrating a routing of metal lines in multiple layers in accordance with some embodiments.

FIG. 12 is a top view illustrating a device cell in accordance with some embodiments.

FIG. 13 is a top view illustrating a device cell in accordance with some embodiments.

FIG. 14 is a top view illustrating a device cell in accordance with some embodiments.

FIG. 15 is a top view illustrating a device cell in accordance with some embodiments.

FIG. 16 is a top view illustrating a device cell in accordance with some embodiments.

FIG. 17 is a top view illustrating active regions, gate features and source/drain contacts of the device cell in FIG. 16 in accordance with some embodiments.

FIG. 18 is a top view illustrating metal lines of the device cell in FIG. 16 in accordance with some embodiments.

FIG. 19 is a top view illustrating a device cell in accordance with some embodiments.

FIG. 20 is a top view illustrating active regions, gate features and source/drain contacts of the device cell in FIG. 19 in accordance with some embodiments.

FIG. 21 is a top view illustrating some metal lines of the device cell in FIG. 19 in accordance with some embodiments.

FIG. 22 is a top view illustrating some other metal lines of the device cell in FIG. 19 in accordance with some embodiments.

FIG. 23 is a top view illustrating a device cell in accordance with some embodiments.

FIG. 24 is a top view illustrating a device cell in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

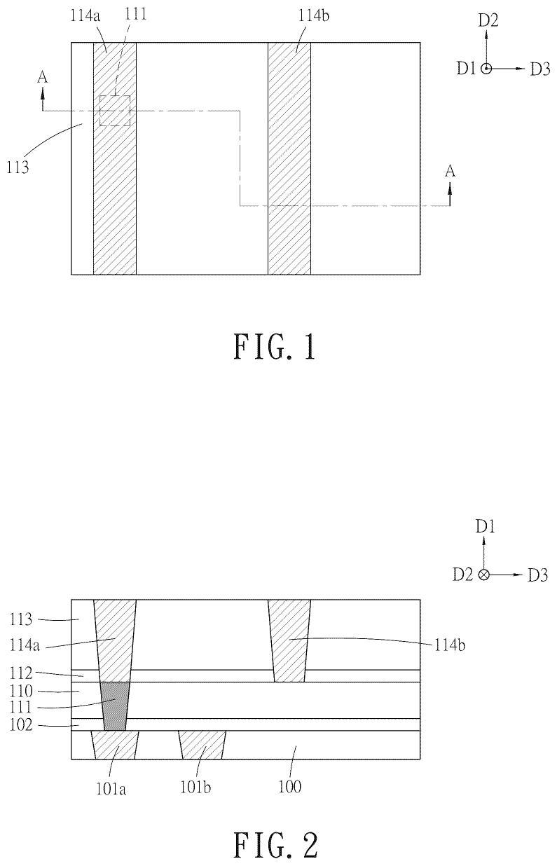

FIG. 1 illustrates a plurality of metal lines 114a, 114b in a first metal line layer when viewed from top (i.e., viewed along a first axis D1 that corresponds to an into-the-page/out-of-the-page direction in FIG. 1). The metal lines 114a, 114b extend along a second axis D2 transverse or perpendicular to the first axis D1, and are distributed along a third axis D3 that is transverse or perpendicular to the first axis D1 and the second axis D2. Referring further to FIG. 2, which illustrates a sectional view taken along line A-A in FIG. 1, the first metal line layer is disposed over a semiconductor substrate 100. In the illustrative embodiment, the first axis D1 is perpendicular to a top surface of the semiconductor substrate 100; the second axis D2 corresponds to a lengthwise direction of the metal lines 114a, 114b (i.e., an up/down direction from the perspective of FIG. 1); and the third axis D3 corresponds to a widthwise direction of the metal lines 114a, 114b (i.e., a left/right direction from the perspective of FIG. 1).

The semiconductor substrate 100 may be a bulk semiconductor substrate or a semiconductor-on-insulator (SOI) substrate, which may be doped (e.g., with a p-type dopant or an n-type dopant) or undoped. In some embodiments, an SOI substrate includes a layer of a semiconductor material formed on an insulator layer. The insulator layer may be a buried oxide (BOX) layer, a silicon oxide layer or any other suitable layers. The insulator layer may be provided on a suitable substrate, such as silicon, glass or the like. The semiconductor substrate 100 may be made of a suitable semiconductor material, such as silicon or the like. In some embodiments, the semiconductor substrate 100 is a silicon wafer; and in other embodiments, the semiconductor substrate 100 is made of a compound semiconductor such as silicon carbide, gallium arsenide, indium arsenide, indium phosphide or other suitable materials. In still other embodiments, the semiconductor substrate 100 is made of an alloy semiconductor such as GaAsP, AlInAs, AlGaAs, GaInAs, GaInP, GaInAsP or other suitable materials.

In some embodiments, the semiconductor substrate 100 includes various p-type doped regions and/or n-type doped regions, such as p-type wells, n-type wells, p-type source/drain features and/or n-type source/drain features, formed by a suitable process such as ion implantation, thermal diffusion, a combination thereof, or the like. In some embodiments, the semiconductor substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The semiconductor substrate 100 may include lateral isolation features (e.g., shallow trench isolation (STI)) configured to separate various functional elements formed on and/or in the semiconductor substrate 100.

In the illustrative embodiment, the semiconductor substrate 100 includes conductive features 101a, 101b. In accordance with some embodiments, the conductive features 101a, 101b may be disposed in or on a device region where a plurality of transistors (not shown) are disposed, and each of the conductive features 101a, 101b may be, for example, a source/drain contact that is coupled to a source/drain feature of a transistor (not shown), a gate feature of a transistor, a metal line disposed in an interconnect layer (e.g., a metal line layer), other types of conductive components, etc. In accordance with some embodiments, the conductive features 101a, 101b may be disposed in and surrounded by an interlayer dielectric or an intermetal dielectric. Above the device region is an etch stop layer 102 disposed. An interlayer dielectric (ILD) 110 is disposed over the etch stop layer 102, and a metal via 111 is disposed in the interlayer dielectric 110 and extends through the etch stop layer 102 along the first axis D1 to connect with the conductive feature 101a. In accordance with some embodiments, the interlayer dielectric 110 is in contact with the etch stop layer 102. An etch stop layer 112 is disposed over and in contact with the interlayer dielectric 110. An intermetal dielectric (IMD) 113 is disposed over and in contact with the etch stop layer 112, and the metal lines 114a, 114b are disposed in and surrounded by the intermetal dielectric 113, and extend through the intermetal dielectric 113 and the etch stop layer 112 along the first axis D1. The metal line 114a corresponds in position to the metal via 111 along the first axis D1, and is connected to the metal via 111. In accordance with some embodiments, the etch stop layer 102 is deposited on the semiconductor substrate 100, and the interlayer dielectric 110 is deposited over the etch stop layer 102. A lithographic process may be performed to form a via hole (not shown) extending through the interlayer dielectric 110 and the etch stop layer 102 to expose the conductive feature 101a. In accordance with some embodiments, a patterned photoresist layer (not shown) may be coated over the interlayer dielectric 110 to have an opening (not shown) exposing a portion of the interlayer dielectric 110 that corresponds in position to the conductive feature 101a along the first axis D1. Then, the interlayer dielectric 110 and the etch stop layer 102 are etched through the opening, forming the via hole that partially exposes the conductive feature 101a. A metalization process may be subsequently performed to fill the via hole with metal, followed by a planarization process (e.g., a chemical mechanical planarization (CMP) process) to remove excessive metal above the interlayer dielectric 110, thereby forming the metal via 111. Then, the etch stop layer 112 is deposited over the interlayer dielectric 110 and the metal via 111, the intermetal dielectric 113 is deposited over the etch stop layer 112, and a lithographic process may be performed to form trenches (not shown) in the intermetal dielectric 113, where one of the trenches exposes the metal via 111. A metalization process may be subsequently performed to fill the trenches with metal, followed by a planarization process to remove excessive metal above the intermetal dielectric 113, thereby forming the metal lines 114a, 114b.

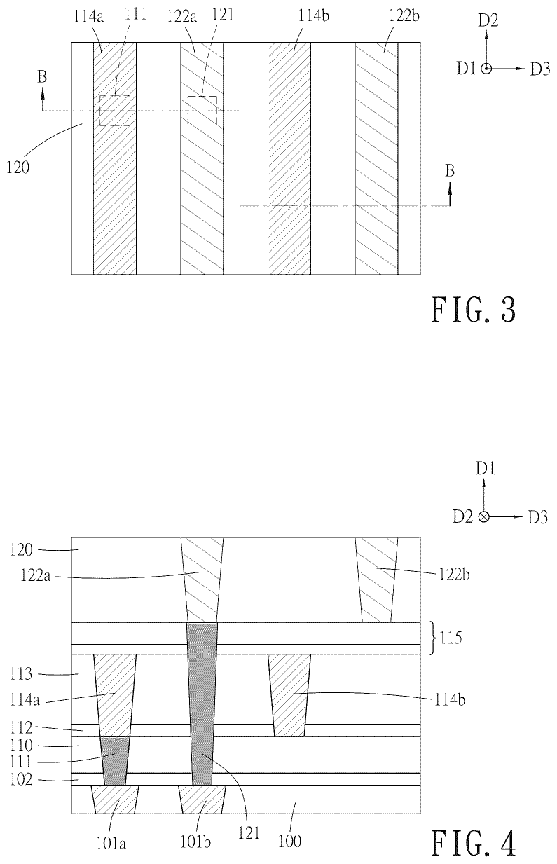

FIG. 3 further illustrates a plurality of metal lines 122a, 122b in a second metal line layer that is disposed over and adjacent to the first metal line layer. The metal lines 122a, 122b extend along the second axis D2 (i.e., the second axis D2 corresponds to a lengthwise direction of the metal lines 122a, 122b) and are distributed along the third axis D3. From the perspective of FIG. 3 (i.e., viewed from top or along the first axis D1), the metal lines 114a, 114b, 122a, 122b are spaced apart from and parallel to each other. In accordance with some embodiments, pitches among the metal lines 114a, 114b, 122a, 122b may be the same, and may be in a range from about 20 nm to about 30 nm. A spacing between the metal lines 114a, 114b along the third axis D3 is greater than a width of at least one of the metal lines 122a, 122b, and a spacing between the metal lines 122a, 122b along the third axis D3 is greater than a width of at least one of the metal lines 114a, 114b. In accordance with some embodiments, a spacing between the metal lines 114a, 114b along the third axis D3 is not smaller than 1.5 times the width of at least one of the metal lines 122a, 122b, and a spacing between the metal lines 122a, 122b along the third axis D3 is not smaller than 1.5 times the width of at least one of the metal lines 114a, 114b. In accordance with some embodiments, a spacing between the metal lines 114a, 114b along the third axis D3 is not smaller than twice the width of at least one of the metal lines 122a, 122b, and a spacing between the metal lines 122a, 122b along the third axis D3 is not smaller than twice the width of at least one of the metal lines 114a, 114b. Referring further to FIG. 4, which illustrates a sectional view taken along line B-B in FIG. 3, an etch stop layer 115 is disposed over and in contact with the intermetal dielectric 113, and an intermetal dielectric 120 is disposed over and in contact with the etch stop layer 115. The metal lines 122a, 122b are disposed in and surrounded by the intermetal dielectric 120, and extend through the intermetal dielectric 120 along the first axis D1, where the metal line 122a corresponds in position to the conductive feature 101b along the first axis D1. A metal via 121 extends through the etch stop layer 102, the interlayer dielectric 110, the etch stop layer 112, the intermetal dielectric 113 and the etch stop layer 115 from a top surface of the conductive feature 101b to a bottom surface of the metal line 122a along the first axis D1, thereby interconnecting the conductive feature 101b and the metal line 122a. A distance between any one of the metal lines 114a, 114b and any one of the metal lines 122a, 122b along the first axis D1 is smaller than a thickness of any one of the metal lines 114a, 114b, 122a, 122b, a thickness of each of the intermetal dielectric layers 113, 120, and a thickness of each metal via in a back-end-of-line (BEOL) interconnect structure along the first axis D1. In accordance with some embodiments, the distance between any one of the metal lines 114a, 114b and any one of the metal lines 122a, 122b along the first axis D1 is equal to a thickness of the etch stop layer 115 that is disposed between and separates the intermetal dielectrics 113, 120 from each other, but this disclosure is not limited in this respect. By virtue of the configuration where the metal lines 114a, 114b, 122a, 122b that extend in the same direction (e.g., along the second axis D2) are separately formed in multiple adjacent layers (e.g., the first metal line layer and the second metal line layer), a spacing between adjacent metal lines (e.g., between the metal lines 114a, 114b and/or between the metal lines 122a, 122b, which are adjacent along their widthwise direction) may be released or increased, and thus capacitance among the metal lines in the same metal line layer can be reduced in comparison to all of the metal lines 114a, 114b, 122a, 122b being formed in the same metal line layer.

In accordance with some embodiments, the etch stop layer 115 is deposited on the intermetal dielectric 113 and the metal lines 114a, 114b, and a lithographic process may be performed to form a deep via hole (not shown) extending through the etch stop layer 115, the intermetal dielectric 113, the etch stop layer 112, the interlayer dielectric 110 and the etch stop layer 102 to expose the conductive feature 101b. In accordance with some embodiments, a patterned photoresist layer (not shown) may be coated over the etch stop layer 115 to have an opening (not shown) exposing a portion of the etch stop layer 115 that corresponds in position to the conductive feature 101b along the first axis D1. Then, the etch stop layer 115, the intermetal dielectric 113, the etch stop layer 112, the interlayer dielectric 110 and the etch stop layer 102 are etched through the opening, forming the deep via hole that partially exposes the conductive feature 101b. A metalization process may be subsequently performed to fill the deep via hole with metal, followed by a planarization process to remove excessive metal above the etch stop layer 115, thereby forming the metal via 121. Then, the intermetal dielectric 120 is deposited over the etch stop layer 115 and the metal via 121, and a lithographic process may be performed to form trenches (not shown) in the intermetal dielectric 120, where one of the trenches exposes the metal via 121. A metalization process may be subsequently performed to fill the trenches with metal, followed by a planarization process to remove excessive metal above the intermetal dielectric 120, thereby forming the metal lines 122a, 122b.

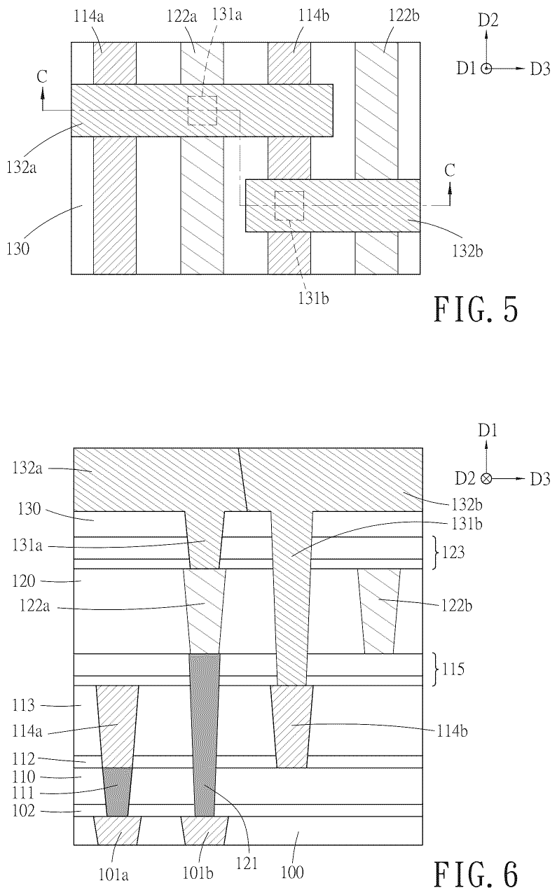

FIG. 5 further illustrates a plurality of metal lines 132a, 132b in a third metal line layer that is disposed over and adjacent to the second metal line layer. The metal lines 132a, 132b extend across some of the metal lines 114a, 114b, 122a, 122b along the third axis D3 (i.e., the third axis D3 corresponds to a lengthwise direction of the metal lines 132a, 132b) and are distributed along the second axis D2. Referring further to FIG. 6, which illustrates a sectional view taken along line C-C in FIG. 5, an etch stop layer 123 is disposed over and in contact with the intermetal dielectric 120, and an intermetal dielectric 130 is disposed over and in contact with the etch stop layer 123. The metal lines 132a, 132b are disposed in and surrounded by the intermetal dielectric 130. A metal via 131a extends through the etch stop layer 123 and the intermetal dielectric 130 from a top surface of the metal line 122a to a bottom surface of the metal line 132a along the first axis D1, thereby interconnecting the metal line 122a and the metal line 132a. A metal via 131b extends through the etch stop layer 115, the intermetal dielectric 120, the etch stop layer 123 and the intermetal dielectric 130 from a top surface of the metal line 114b to a bottom surface of the metal line 132b along the first axis D1, thereby interconnecting the metal line 114b and the metal line 132b. In accordance with some embodiments, the metal vias 131a, 131b and the metal lines 132a, 132b may be formed using, for example, a single damascene process, a dual damascene process, other suitable processes, or any combination thereof.

In accordance with some embodiments, each of the etch stop layers 102, 112, 115, 123 may be deposited using, for example, physical vapor deposition (PVD), chemical vapor deposition (CVD), plasma-enhanced chemical vapor deposition (PECVD), atomic layer deposition (ALD), other suitable deposition techniques, or any combination thereof. In accordance with some embodiments, each of the etch stop layers 102, 112, 115, 123 may have a single-layered structure or a multi-layered structure, and may be made out of or include, for example, silicon carbonitride (SiCₓN_{y}), silicon oxide (SiOₓ), silicon nitride (SiNₓ), aluminum oxynitride (AlOₓN_{y}), metal oxide (e.g., including metal element such as Ru, W, Ti, Al, Co, etc.), other suitable materials, or any combination thereof. In accordance with some embodiments, each of the etch stop layers 102, 112, 115, 123 may have a thickness in a range from about 4 nm to about 10 nm. In accordance with some embodiments, one or more of the etch stop layers 102, 112, 115, 123 may be omitted. In accordance with some embodiments, each of the dielectrics 110, 113, 120, 130 may be deposited using, for example, PVD, CVD, PECVD, ALD, other suitable deposition techniques, or any combination thereof. In accordance with some embodiments, each of the dielectrics 110, 113, 120, 130 may be made out of or include, for example, silicon oxide, nitride or carbide (e.g., SiOₓ, SiNₓ, SiOₓC_{y}, SiOₓC_{y}N_{z}, etc.), metal oxide, nitride or carbide (e.g., AlOₓ, AlOₓN_{y}, AlOₓC_{y}, etc.), oxygen-doped silicon carbide (ODC), nitrogen-doped silicon carbide (NDC), tetraethoxysilane (TEOS) oxide, plasma-enhanced oxide (PEOX), other suitable materials, or any combination thereof. In accordance with some embodiments, each of the dielectrics 110, 113, 120, 130 may have a thickness in a range from about 20 nm to about 40 nm. In accordance with some embodiments, each of the metalization processes may use, for example, PVD, CVD, PECVD, ALD, electrochemical plating (ECP), other suitable deposition techniques, or any combination thereof. In accordance with some embodiments, the metal formed in each of the metalization processes may include, for example, Cu, Ru, W, Ti, Al, Co, Mo, Ir, Rh, C, NiₓAl_{y}, CuₓAl_{y}, ScₓAl_{y}, RuₓAl_{y}, other suitable conductors, or any combination thereof.

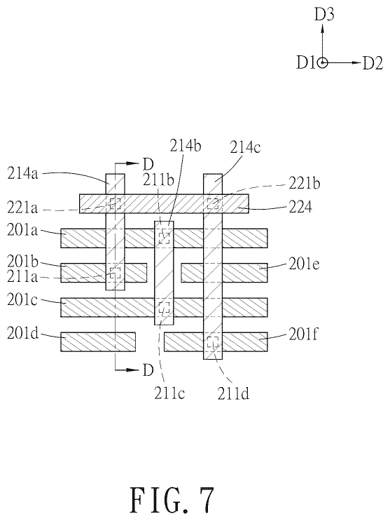

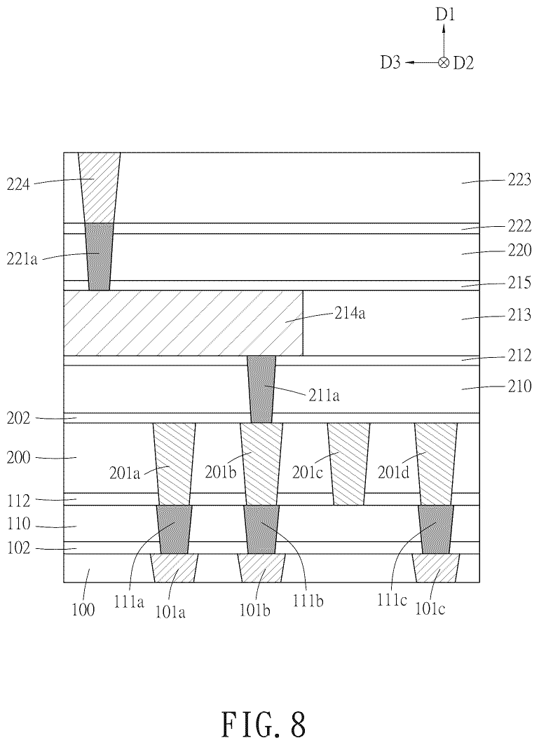

FIG. 7 illustrates a routing of metal lines in multiple layers in accordance with some embodiments. Referring further to FIG. 8, which illustrates a sectional view taken along line D-D in FIG. 7, a first metal line layer is disposed on a device region of a semiconductor substrate 100, and includes metal lines 201a, 201b, 201c, 201d, 201e, 201f that are disposed in and surrounded by an intermetal dielectric 200. The metal lines 201a, 201b, 201c, 201d extend along the second axis D2 (corresponding to a left/right direction from the perspective of FIG. 7) and are distributed along the third axis D3 (corresponding to an up/down direction from the perspective of FIG. 7); the metal line 201e is spaced apart from and aligned with the metal line 201b along the second axis D2; the metal line 201f is spaced apart from and aligned with the metal line 201d along the second axis D2. The metal lines 201a, 201b, 201d are respectively connected to conductive features 101a, 101b, 101c. The conductive features 101a, 101b, 101c are disposed in the semiconductor substrate 100 respectively through metal vias 111a, 111b, 111c that are disposed in an interlayer dielectric 110 and included in a first metal via layer. In accordance with some embodiments, the interlayer dielectric 110 is separated from the semiconductor substrate 100 by an etch stop layer 102, and is separated from the intermetal dielectric 200 by an etch stop layer 112. A second metal line layer is disposed over the first metal line layer along the first axis D1, and includes metal lines 214a, 214b, 214c that are disposed in and surrounded by an intermetal dielectric 213. The metal lines 214a, 214b, 214c extend along the third axis D3, and are distributed along the second axis D2. The metal line 214a extends across and overlaps the metal lines 201a, 201b, and is electrically connected to the metal line 201b through a metal via 211a. The metal line 214b extends across and overlaps the metal lines 201a, 201c, and is electrically connected to the metal lines 201a, 201c through metal vias 211b, 211c, respectively. The metal line 214c extends across and overlaps the metal lines 201a, 201e, 201c, 201f, and is electrically connected to the metal line 201f through a metal via 211d. The metal vias 211a, 211b, 211c, 211d are disposed in and surrounded by an intermetal dielectric 210, and are included in a second metal via layer. In accordance with some embodiments, the intermetal dielectric 210 is separated from the intermetal dielectric 200 by an etch stop layer 202, and is separated from the intermetal dielectric 213 by an etch stop layer 212. A third metal line layer is disposed over the second metal line layer along the first axis D1, and includes a metal line 224 that is disposed in and surrounded by an intermetal dielectric 223. The metal line 224 extends across the metal lines 214a, 214c along the second axis D2, overlaps the metal lines 214a, 214c along the first axis D1, and is electrically connected to the metal lines 214a, 214c through metal vias 221a, 221b, respectively. The metal vias 221a, 221b are disposed in and surrounded by an intermetal dielectric 220, and are included in a third metal via layer. In accordance with some embodiments, the intermetal dielectric 220 is separated from the intermetal dielectric 213 by an etch stop layer 215, and is separated from the intermetal dielectric 223 by an etch stop layer 222. In accordance with some embodiments, one or more of the etch stop layers 102, 112, 202, 212, 215, 222 may be omitted, and this disclosure is not limited in this respect. Through the illustrative configuration, the metal line 201b is electrically connected to the metal line 201f through the metal via 211a, the metal line 214a, the metal via 221a, the metal line 224, the metal via 221b, the metal line 214c and the metal via 211d; and the metal line 201a is electrically connected to the metal line 201c through the metal via 211b, the metal line 214b and the metal via 211c.

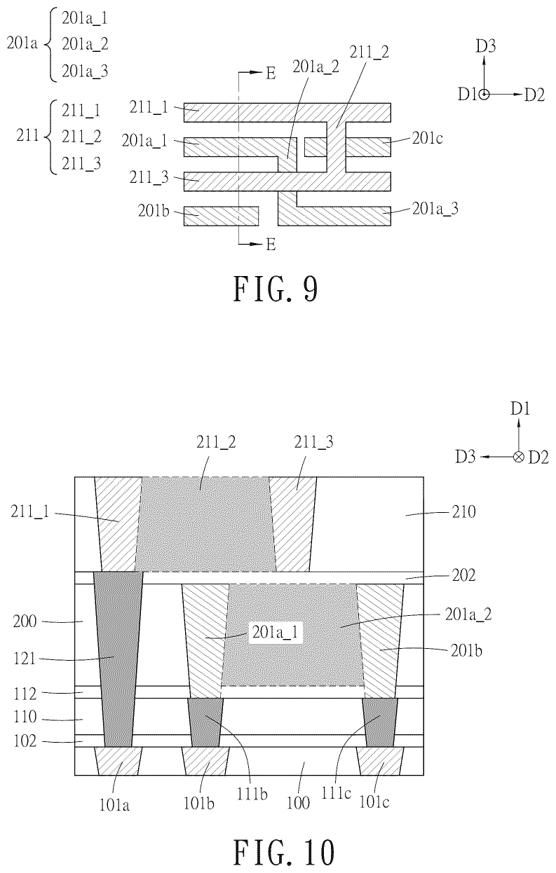

FIG. 9 illustrates a routing of metal lines in multiple layers in accordance with some embodiments. Referring further to FIG. 10, which illustrates a sectional view taken along line E-E in FIG. 9, a first metal line layer is disposed on a device region of a semiconductor substrate 100, and includes metal lines 201a_1, 201a_2, 201a_3, 201b, 201c that are disposed in and surrounded by an intermetal dielectric 200, where the metal lines 201a_1, 201a_3, 201b, 201c extend along the second axis D2, and the metal line 201a_2 extends along the third axis D3 and interconnects the metal lines 201a_1, 201a_3 to form a metal interconnect network 201a. The metal line 201c is spaced apart from and aligned with the metal line 201a_1 along the second axis D2, and the metal line 201a_3 is spaced apart from and aligned with the metal line 201b along the second axis D2. The metal lines 201a_1, 201b are respectively connected to conductive features 101b, 101c. The conductive features 101b, 101c are disposed in the semiconductor substrate 100 respectively through metal vias 111b, 111c that are disposed in and surrounded by an interlayer dielectric 110 and that are included in a first metal via layer. In accordance with some embodiments, the interlayer dielectric 110 is separated from the semiconductor substrate 100 by an etch stop layer 102, and is separated from the intermetal dielectric 200 by an etch stop layer 112. A second metal line layer is disposed over and adjacent to the first metal line layer along the first axis D1, and includes metal lines 211_1, 211_2, 211_3 that are disposed in and surrounded by an intermetal dielectric 210 and that constitute a metal line network 211. The metal lines 211_1, 211_3 extend along the second axis D2, and are distributed along the third axis D3. The metal line 211_2 extends across the metal line 201c along the third axis D3, and interconnects the metal lines 211_1, 211_3. The metal line 211_1 is electrically connected to a conductive feature 101a that is disposed in the semiconductor substrate 100 through a deep metal via 121 that extends through the etch stop layer 102, the interlayer dielectric 110, the etch stop layer 112, the intermetal dielectric 200 and an etch stop layer 202 from a top surface of the conductive feature 101a to a bottom surface of the metal line 211_1, where the etch stop layer 202 is disposed between the intermetal dielectric 200 and the intermetal dielectric 210. In accordance with some embodiments, one or more of the etch stop layers 102, 112, 202 may be omitted, and this disclosure is not limited in this respect. In the illustrative embodiment shown in FIG. 9, the metal lines 211_1, 201a_1, 211_3, 201b, 201c, 201a_3 respectively correspond to the metal lines 201a, 201b, 201c, 201d, 201e, 201f shown in FIG. 7. In FIG. 9, the metal line 201a_1 is electrically connected to the metal line 201a_3 through the metal line 201a_2 that is formed in the same layer (i.e., the first metal line layer), and the metal line 211_1 is electrically connected to the metal line 211_3 through the metal line 211_2 that is formed in the same layer (i.e., the second metal line layer). Compared to the configuration illustrated in FIGS. 7 and 8, the configuration illustrated in FIGS. 9 and 10 achieves the same interconnection with fewer layers (e.g., the second metal via layer, the third metal via layer and the third metal line layer in FIG. 8 are omitted). As a result, the manufacturing process for the configuration illustrated in FIGS. 9 and 10 may be simplified and more efficient, and a space for a third metal line layer, which may be subsequently formed over the second metal line layer, may be released to accommodate other wirings. From the perspective of FIG. 9 (i.e., viewed from top or along the first axis D1), the metal lines 211_1, 201a_1, 211_3, 201b are spaced apart from and parallel to each other along the third axis D3; the metal lines 211_1, 201c, 211_3, 201a_3 are spaced apart from and parallel to each other along the third axis D3; and the metal lines 201a_2, 211_2 are spaced apart from and parallel to each other along the second axis D2. In accordance with some embodiments, a spacing between the metal lines that are adjacent along the third axis D3 in the first metal line layer (e.g., the metal lines 201a_1, 201b, the metal lines 201c, 201a_3, etc.) is greater than a width of at least the narrowest one of the metal lines that extends along the second axis D2 and that is disposed in the second metal line layer (e.g., the metal lines 211_1, 211_3, etc.), and a spacing between the metal lines that are adjacent along the third axis D3 in the second metal line layer (e.g., the metal lines 211_1, 211_3, etc.) is greater than a width of at least the narrowest one of the metal lines that extends along the second axis D2 and that is disposed in the first metal line layer (e.g., the metal lines 201a_1, 201b, 201c, 201a_3). In accordance with some embodiments, a spacing between the metal lines that are adjacent along the third axis D3 in the first metal line layer is not smaller than 1.5 times the width of at least the narrowest one of the metal lines that extends along the second axis D2 and that is disposed in the second metal line layer, and a spacing between the metal lines that are adjacent along the third axis D3 in the second metal line layer is not smaller than 1.5 times the width of at least the narrowest one of the metal lines that extends along the second axis D2 and that is disposed in the first metal line layer. In accordance with some embodiments, a spacing between the metal lines that are adjacent along the third axis D3 in the first metal line layer is not smaller than twice the width of at least the narrowest one of the metal lines that extends in along the second axis D2 and that is disposed in the second metal line layer, and a spacing between the metal lines that are adjacent along the third axis D3 in the second metal line layer is not smaller than twice the width of at least the narrowest one of the metal lines that extends along the second axis D2 and that is disposed in the first metal line layer. By virtue of this configuration, a distance between the metal lines that are adjacent along their widthwise direction in the same metal line layer is greater than that in the configuration as illustrated in FIGS. 7 and 8 where the metal lines 201a, 201b, 201c, 201d, 201e, 201f are all formed in the same metal line layer, thereby reducing line-to-line capacitance and leading to less power dissipation. In accordance with some embodiments, a distance between the metal lines in the first metal line layer (e.g., the metal lines 201a_1, 201a_2, 201a_3, 201b, 201c) and the metal lines in the second metal line layer (e.g., the metal lines 211_1, 211_2, 211_3) along the first axis D1 is smaller than a thickness of each of the aforesaid metal lines and the intermetal dielectrics 200, 210. In accordance with some embodiments, a distance between the metal lines 201a_1, 201a_2, 201a_3, 201b, 201c in the first metal line layer and the metal lines 211_1, 211_2, 211_3 in the second metal line layer along the first axis D1 is substantially equal to a thickness of the etch stop layer 202.

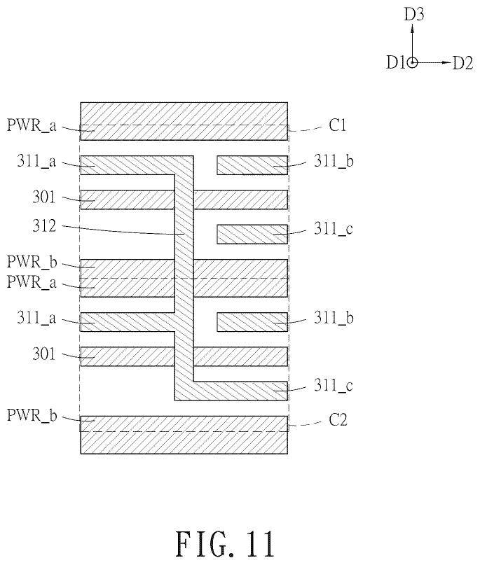

FIG. 11 illustrates a device region that includes a first device cell C1 and a second device cell C2 that are adjacent to each other and have the same configuration (e.g., the same design and arrangement of gate features and source/drain features of transistors, not shown). A first metal line layer is disposed over a semiconductor substrate (e.g., the semiconductor substrate 100 in FIG. 10) along the first axis D1, and a second metal line layer is disposed over and adjacent to the first metal line layer along the first axis D1. For the first device cell C1, the first metal line layer includes a first group of metal lines PWR_a, PWR_b, 301 that extend along the second axis D2 in a first intermetal dielectric (e.g., the intermetal dielectric 200 in FIG. 10) and overlap the first device cell C1 along the first axis D1. For the second device cell C2, the first metal line layer includes a second group of metal lines PWR_a, PWR_b, 301 that extend along the second axis D2 in the first intermetal dielectric and overlap the second device cell C2 along the first axis D1. In accordance with some embodiments, one or more of the metal lines PWR_a, PWR_b, 301 are connected to one or more circuit components (e.g., transistors) of the corresponding device cell. In accordance with some embodiments, an arrangement of the first group of metal lines PWR_a, PWR_b, 301 relative to the first device cell C1 is the same as an arrangement of the second group of metal lines PWR_a, PWR_b, 301 relative to the second device cell C2. In accordance with some embodiments, the metal line PWR_a is disposed at an edge of the device cell, and may combine the metal line PWR_b of an adjacent device cell to form a wider metal line that serves as a power rail; and the metal line PWR_b is disposed at an opposite edge of the device cell, and may combine the metal line PWR_a of another adjacent device cell to form another power rail. For example, a power rail in FIG. 11 is a combination of the metal line PWR_b of the first device cell C1 and the metal line PWR_a of the second device cell C2. For the first device cell C1, the second metal line layer includes a first group of metal lines 311_a, 311_b, 311_c that extend along the second axis D2 in a second intermetal dielectric (e.g., the intermetal dielectric 210 in FIG. 10) and overlap the first device cell C1 along the first axis D1. For the second device cell C2, the second metal line layer includes a second group of metal lines 311_a, 311_b, 311_c that extend along the second axis D2 in the second intermetal dielectric and overlap the second device cell C2 along the first axis D1. In accordance with some embodiments, one of more of the metal lines 311_a, 311_b, 311_c are connected to one or more circuit components (e.g., transistors) of the corresponding device cell. In accordance with some embodiments, an arrangement of the first group of metal lines 311_a, 311_b, 311_c relative to the first device cell C1 is the same as an arrangement of the second group of metal lines 311_a, 311_b, 311_c relative to the second device cell C2. In accordance with some embodiments, either the first metal line layer or the second metal line layer may include one or more metal lines that extend across different device cells and that interconnect metal lines corresponding to different device cells. For example, in FIG. 11, the second metal line layer includes a metal line 312 that extends along the third axis D3 in the second intermetal dielectric and interconnects the metal line 311_a corresponding to the first device cell C1 and the metal lines 311_a, 311_c corresponding to the second device cell C2. From the perspective of FIG. 11 (i.e., viewed from top or along the first axis D1), the power rails and the metal lines 311_a, 301 are spaced apart from and parallel to each other along the third axis D3, and the power rails and the metal lines 311_b, 301, 311_c are spaced apart from and parallel to each other along the third axis D3. A spacing between any two of the metal lines that are adjacent along their widthwise direction in the first metal line layer (e.g., a power rail and an adjacent metal line 301 that extend along the second axis D2) is greater than a width of at least the narrowest one of the metal lines that extend in the same direction (e.g., a direction along the second axis D2) in the second metal line layer, and a spacing between any two of the metal lines that are adjacent along their widthwise direction in the second metal line layer (e.g., the metal lines 311_b, 311_c, or the metal lines 311_a of the first device cell C1 and the second device cell C2 that extend along the second axis D2) is greater than a width of at least the narrowest one of the metal lines that extend in the same direction (e.g., a direction along the second axis D2) in the first metal line layer. In accordance with some embodiments, a spacing between any two of the metal lines that are adjacent along their widthwise direction in the first metal line layer is not smaller than 1.5 times the width of at least the narrowest one of the metal lines that extend in the same direction in the second metal line layer, and a spacing between any two of the metal lines that are adjacent along their widthwise direction in the second metal line layer is not smaller than 1.5 times the width of at least the narrowest one of the metal lines that extend in the same direction in the first metal line layer. In accordance with some embodiments, a spacing between any two of the metal lines that are adjacent along their widthwise direction in the first metal line layer is not smaller than twice times the width of at least the narrowest one of the metal lines that extend in the same direction in the second metal line layer, and a spacing between any two of the metal lines that are adjacent along their widthwise direction in the second metal line layer is not smaller than twice times the width of at least the narrowest one of the metal lines that extend in the same direction in the first metal line layer.

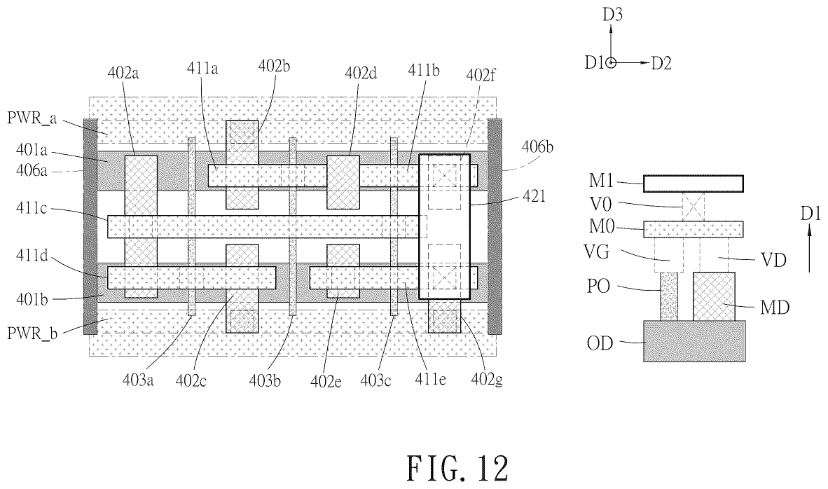

FIG. 12 illustrates a top view of a cell that includes a NOR gate and an inverter connected to an input of the NOR gate, and that is formed on a semiconductor substrate (e.g., the semiconductor substrate 100 in FIG. 8) in accordance with some embodiments, along with a diagram on the right side to illustrate various circuit features represented by various patterns and stacking relationships among the circuit features, where “OD” represents active regions, “MD” represents source/drain contacts, “PO” represents gate features, “M0” represents metal lines in a first metal line layer, “M1” represents metal lines in a second metal line layer, “VG” represents metal vias connected between M0 and PO, “VD” represents metal vias connected between M0 and MD, and “V0” represents metal vias connected between M1 and M0. A device region of the semiconductor substrate includes active regions 401a, 401b (OD) that extend along the second axis D2, source/drain contacts 402a, 402b, 402c, 402d, 402e, 402f, 402g (MD) that extend along the third axis D3, gate features 403a, 403b, 403c (PO) that extend along the third axis D3, and insulating features 406a, 406b that extend along the third axis D3 at opposite sides of the device region. A first metal line layer is disposed on the device region along the first axis D1, and includes metal lines PWR_a, 411a, 411b, 411c, 411d, 411e, PWR_b that extend along the second axis D2 in a first intermetal dielectric (e.g., the intermetal dielectric 200 in FIG. 8). A second metal line layer is disposed on and adjacent to the first metal line layer along the first axis D1, and includes a metal line 421 that extends along the third axis D3 in a second intermetal dielectric (e.g., the intermetal dielectric 213 in FIG. 8). Similar to the configuration in FIGS. 7 and 8, all of the metal lines in the first metal line layer extend in the same direction (i.e., along the second axis D2 in FIG. 12), and all of the metal lines (only the metal line 421 is shown in FIG. 12) in the second metal line layer extend in another direction (i.e., along the third axis D3 in FIG. 12), so there are three rows of metal lines are formed in a limited space between two power rails PWR_a, PWR_b, and the metal lines in different rows have to be connected through one or more metal lines that are disposed in another one or more metal line layers (e.g., the metal lines 411b, 411e are connected together through the metal line 421).

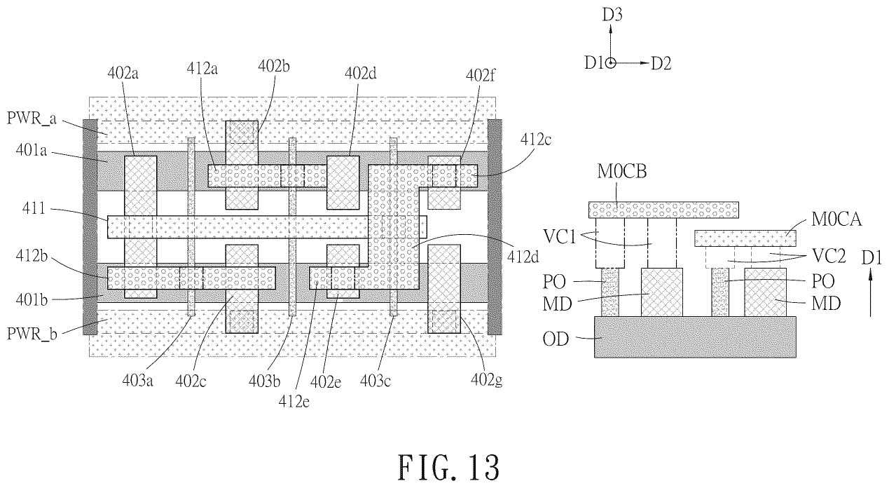

FIG. 13 illustrates a top view of a cell that includes a NOR gate and an inverter connected to an input of the NOR gate, and that is formed on a semiconductor substrate (e.g., the semiconductor substrate 100 in FIG. 10) in accordance with some embodiments, along with a diagram on the right side to illustrate various circuit features represented by various patterns and stacking relationships among the circuit features, where “OD” represents active regions, “MD” represents source/drain contacts, “PO” represents gate features, “M0CA” represents metal lines in a first metal line layer, “M0CB” represents metal lines in a second metal line layer, “VC1” represents metal vias connected between M0CB and PO or between M0CB and MD, and “VC2” represents metal vias connected between M0CA and PO or between M0CA and MD. A device region of the semiconductor substrate includes active regions 401a, 401b (OD) that extend along the second axis D2, source/drain contacts 402a, 402b, 402c, 402d, 402e, 402f, 402g (MD) that extend along the third axis D3, and gate features 403a, 403b, 403c (PO) that extend along the third axis D3. The first metal line layer is disposed on the device region along the first axis D1, and includes metal lines PWR_a, 411, PWR_b that extend along the second axis D2 in a first intermetal dielectric (e.g., the intermetal dielectric 200 in FIG. 10). The second metal line layer is disposed on and adjacent to the first metal line layer along the first axis D1 (i.e., there is no intermetal dielectric disposed between the first metal line layer and the second metal line layer), and includes metal lines 412a, 412b, 412c, 412e that extend along the second axis D2 in a second intermetal dielectric (e.g., the intermetal dielectric 210 in FIG. 10), and a metal line 412d that extends across the metal line 411 along the third axis D3 in the second intermetal dielectric and interconnects the metal lines 412c, 412e. From the perspective of FIG. 13 (i.e., viewed from top or along the first axis D1), the row of the metal lines 412a, 412c, the metal line 411, and the row of the metal lines 412b, 412e are spaced apart from and parallel to each other along the third axis D3, and the metal line 412d overlaps the gate feature 403c and is spaced apart from and parallel to all of the source/drain contacts 402a, 402b, 402c, 402d, 402e, 402f, 402g. The cell illustrated in FIG. 13 has the same logic function as the cell illustrated in FIG. 12, with only an etch stop layer (e.g., the etch stop layer 202 in FIG. 10) being disposed between the first metal line layer (e.g., the layer of M0CA) and the second metal line layer (e.g., the layer of M0CB). As a result, a distance between the metal lines in the first metal line layer and the metal lines in the second metal line layer along the first axis D1 is smaller than a thickness of each of the first intermetal dielectric, the second intermetal dielectric, and the metal lines in the first metal line layer and the second metal line layer, and is substantially equal to a thickness of the etch stop layer. In FIG. 13, since the metal lines 412a, 412b, 412c, 412e, which respectively correspond to the metal lines 411a, 411d, 411b, 411e in FIG. 12, are disposed in the second metal line layer while the metal line 411 that corresponds to the metal line 411c in FIG. 12 is disposed in the first metal line layer, spacings among the metal lines in the same metal line layer along the third axis D3 increase, thereby achieving less line-to-line capacitance, and reducing power dissipation. In accordance with some embodiments, a spacing between any two of the metal lines that are adjacent along their widthwise direction in the first metal line layer (e.g., a spacing between the metal lines PWR_a, 411, a spacing between the metal lines 411, PWR_b, etc.) is not smaller than a width of at least the narrowest one of the metal lines that extend in the same direction (e.g., a direction along the second axis D2 in FIG. 13) in the second metal line layer, and a spacing between any two of the metal lines that are adjacent along their widthwise direction in the second metal line layer (e.g., a spacing between the metal lines 412a, 412b, a spacing between the metal lines 412c, 412e) is not smaller than a width of at least the narrowest one of the metal lines that extend in the same direction (e.g., a direction along the second axis D2 in FIG. 13) in the first metal line layer. In accordance with some embodiments, a spacing between any two of the metal lines that are adjacent along their widthwise direction in the first metal line layer is not smaller than 1.5 times the width of at least the narrowest one of the metal lines that extend in the same direction in the second metal line layer, and a spacing between any two of the metal lines that are adjacent along their widthwise direction in the second metal line layer is not smaller than 1.5 times the width of at least the narrowest one of the metal lines that extend in the same direction in the first metal line layer. In accordance with some embodiments, a spacing between any two of the metal lines that are adjacent along their widthwise direction in the first metal line layer is not smaller than twice the width of at least the narrowest one of the metal lines that extend in the same direction in the second metal line layer, and a spacing between any two of the metal lines that are adjacent along their widthwise direction in the second metal line layer is not smaller than twice the width of at least the narrowest one of the metal lines that extend in the same direction in the first metal line layer.

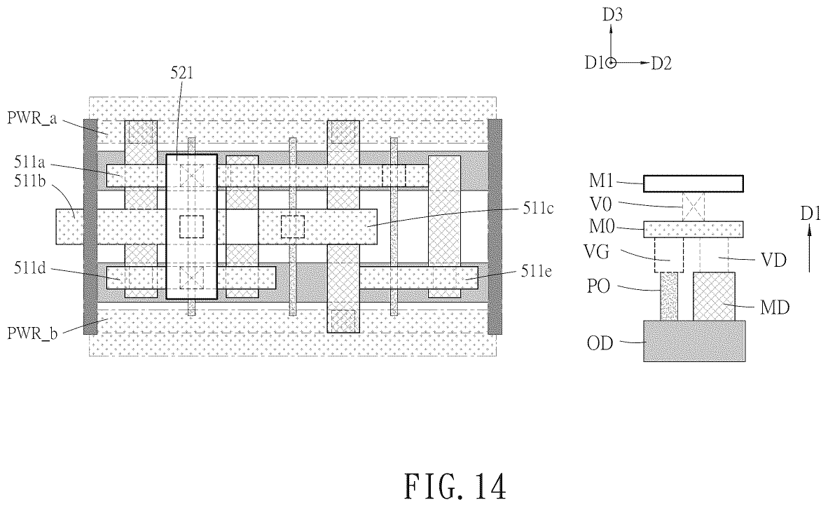

FIG. 14 illustrates a top view of a cell of an AND gate formed on a semiconductor substrate (e.g., the semiconductor substrate 100 in FIG. 8) in accordance with some embodiments, along with a diagram on the right side to illustrate various circuit features represented by various patterns and stacking relationships among the circuit features, where “OD” represents active regions, “MD” represents source/drain contacts, “PO” represents gate features, “M0” represents metal lines in a first metal line layer, “M1” represents metal lines in a second metal line layer, “VG” represents metal vias connected between M0 and PO, “VD” represents metal vias connected between M0 and MD, and “V0” represents metal vias connected between M1 and M0. The metal lines in the first metal line layer (e.g., metal lines 511a, 511b, 511c, 511d, 511e) extend only in one direction (i.e., along the second axis D2 in FIG. 14) in a first intermetal dielectric (e.g. the intermetal dielectric 200 in FIG. 8), and the metal lines in the second metal line layer (only a metal line 521 is shown in FIG. 14) extend only in another direction (i.e., along the third axis D3 in FIG. 14) in a second intermetal dielectric (e.g., the intermetal dielectric 213 in FIG. 8). The first metal line layer includes three rows of metal lines in a limited space between two power rails PWR_a, PWR_b, and the metal lines in different rows are connected through one or more metal lines that are disposed in another one or more metal line layers (e.g., the metal lines 511a, 511d are connected together through the metal line 521).

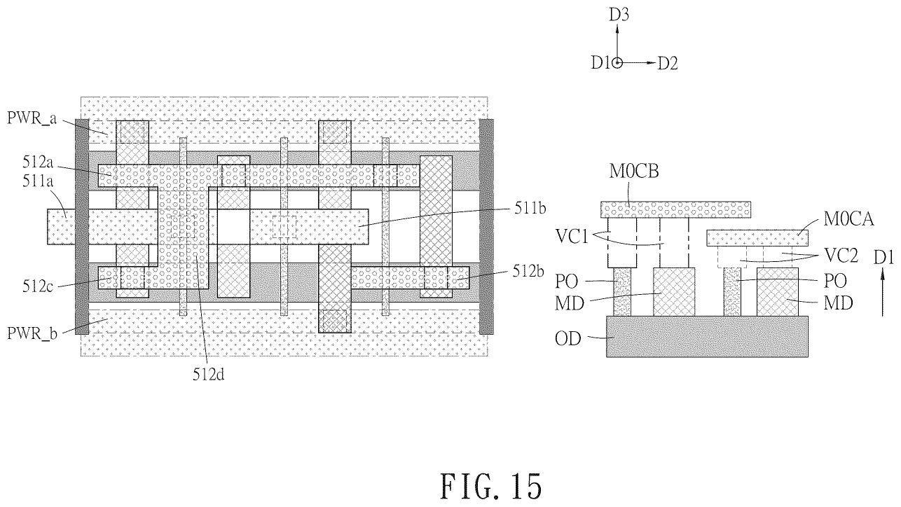

FIG. 15 illustrates a top view of a cell of an AND gate formed on a semiconductor substrate (e.g., the semiconductor substrate 100 in FIG. 10) in accordance with some embodiments, along with a diagram on the right side to illustrate various circuit features represented by various patterns and stacking relationships among the circuit features, where “OD” represents active regions, “MD” represents source/drain contacts, “PO” represents gate features, “M0CA” represents metal lines in a first metal line layer that is disposed on the semiconductor substrate along the first axis D1, “M0CB” represents metal lines in a second metal line layer that is disposed on and adjacent to the first metal line layer along the first axis D1 (i.e., there is no intermetal dielectric disposed between the first metal line layer and the second metal line layer), “VC1” represents metal vias connected between M0CB and PO or between M0CB and MD, and “VC2” represents metal vias connected between M0CA and PO or between M0CA and MD. The first metal line layer includes metal lines 511a, 511b extending along the second axis D2. The second metal line layer includes metal lines 512a, 512b, 512c extending along the second axis D2, and a metal line 512d extending across the metal line 511a along the third axis D3 to interconnect the metal lines 512a, 512c. From the perspective of FIG. 15 (i.e., viewed from top or along the first axis D1), the metal line 512a, the row of the metal lines 511a, 511b, and the row of the metal lines 512b, 512c are spaced apart from and parallel to each other along the third axis D3, and the metal line 512d overlaps one of the gate features, and is spaced apart from and parallel to all of the source/drain contacts. The cell of the AND gate illustrated in FIG. 15 has the same logic function as the cell of the AND gate illustrated in FIG. 14, with only an etch stop layer (e.g., the etch stop layer 202 in FIG. 10) being disposed between the first metal line layer (e.g., the layer of M0CA) and the second metal line layer (e.g., the layer of M0CB). As a result, a distance between the metal lines in the first metal line layer and the metal lines in the second metal line layer along the first axis D1 is smaller than a thickness of each of the first intermetal dielectric, the second intermetal dielectric, and the metal lines in the first metal line layer and the second metal line layer, and is substantially equal to a thickness of the etch stop layer. In FIG. 15, since the metal lines 512a, 512b, 512c, which respectively correspond to the metal lines 511a, 511e, 511d in FIG. 14, are disposed in the second metal line layer while the metal lines 511a, 511b respectively correspond to the metal lines 511b, 511c in FIG. 14, spacings among the metal lines in the same metal line layer along the third axis D3 increase, thereby achieving less line-to-line capacitance, and reducing power dissipation. In accordance with some embodiments, a spacing between any two of the metal lines that are adjacent along their widthwise direction in the first metal line layer (e.g., a spacing between a power rail PWR_a (or PWR_b) and the metal line 511a, a spacing between a power rail PWR_a (or PWR_b) and the metal line 511b, etc.) is not smaller than a width of at least the narrowest one of the metal lines that extend in the same direction (e.g., a direction along the second axis D2) in the second metal line layer, and a spacing between any two of the metal lines that are adjacent along their widthwise direction in the second metal line layer (e.g., a spacing between the metal lines 512a, 512b, a spacing between the metal lines 512a, 512c) is not smaller than a width of at least the narrowest one of the metal lines that extend in the same direction (e.g., a direction along the second axis D2) in the first metal line layer. In accordance with some embodiments, a spacing between any two of the metal lines that are adjacent along their widthwise direction in the first metal line layer is not smaller than 1.5 times the width of at least the narrowest one of the metal lines that extend in the same direction in the second metal line layer, and a spacing between any two of the metal lines that are adjacent along their widthwise direction in the second metal line layer is not smaller than 1.5 times the width of at least the narrowest one of the metal lines that extend in the same direction in the first metal line layer. In accordance with some embodiments, a spacing between any two of the metal lines that are adjacent along their widthwise direction in the first metal line layer is not smaller than twice the width of at least the narrowest one of the metal lines that extend in the same direction in the second metal line layer, and a spacing between any two of the metal lines that are adjacent along their widthwise direction in the second metal line layer is not smaller than twice the width of at least the narrowest one of the metal lines that extend in the same direction in the first metal line layer.

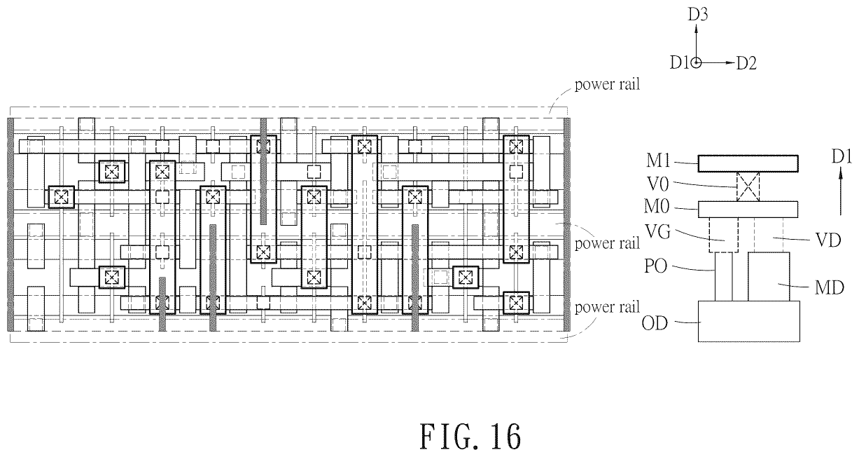

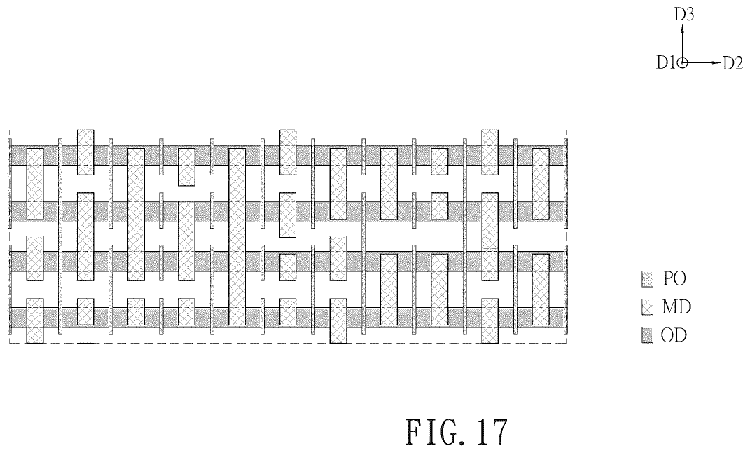

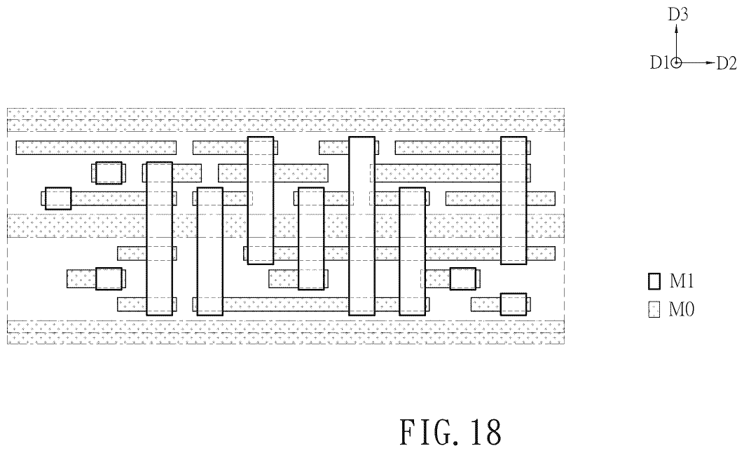

FIG. 16 illustrates a top view of a cell of a D flip-flop in accordance with some embodiments, where a layout of active regions (OD), source/drain contacts (MD) and gate features (PO) of the cell is shown in FIG. 17, and a layout of metal lines in a first metal line layer (M0) and metal lines in a second metal line layer (M1) of the cell is shown in FIG. 18. Similar to the configurations shown in FIGS. 12 and 14, all of the metal lines in the first metal line layer extend in the same direction (e.g., along the second axis D2 in FIG. 16 or 18), and all of the metal lines in the second metal line layer extend in another direction (e.g., along the third axis D3 in FIG. 16 or 18). It is noted that the term “metal line” refers to a metal element that contributes to electrical connection along a lateral direction. In a case where a metal element does not contribute to electrical connection in a lateral direction, it is known as a metal pad rather than a metal line. It can be seen from FIG. 17 that the cell includes twenty-two contact gate pitches (CGPs, also known as contact poly pitches, CPPs), which reflects a size of the cell.

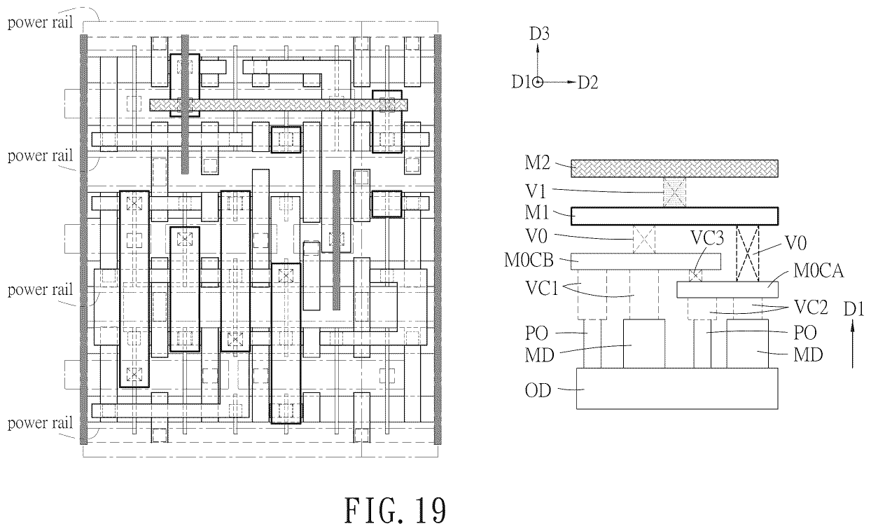

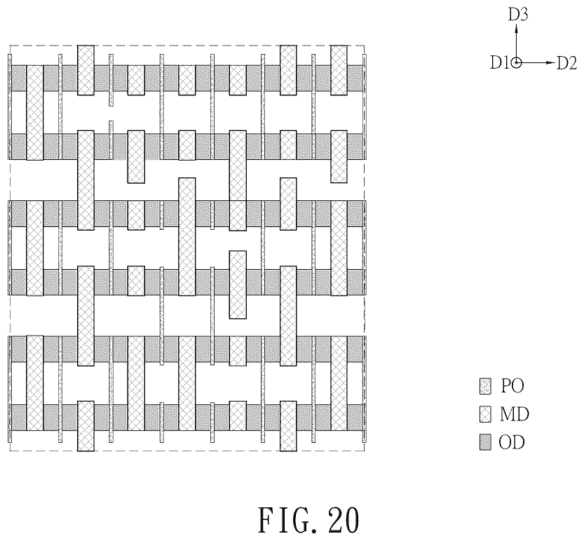

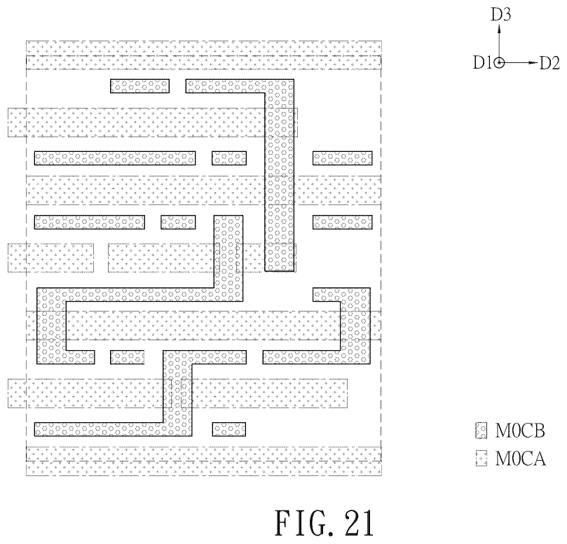

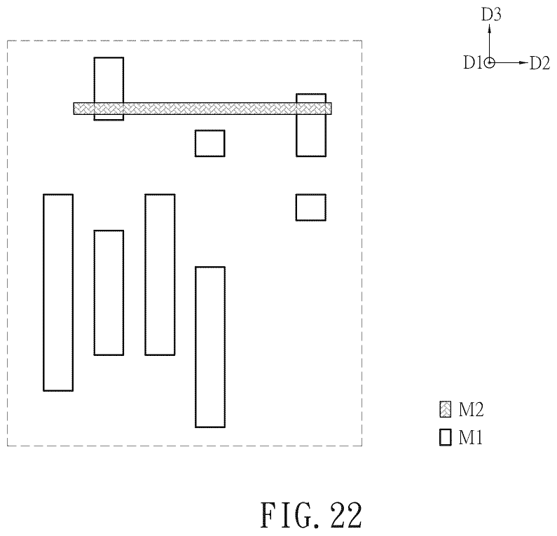

FIG. 19 illustrates a top view of a cell of a D flip-flop in accordance with some embodiments, where a layout of active regions (OD), source/drain contacts (MD) and gate features (PO) is shown in FIG. 20, a layout of metal lines in a first metal line layer (M0CA) and metal lines in a second metal line layer (M0CB) that is disposed on and adjacent to the first metal line layer (i.e., there is no intermetal dielectric disposed between the first metal line layer and the second metal line layer) is shown in FIG. 21, and a layout of metal lines in a third metal line layer (M1) and metal lines in a fourth metal line layer (M2) is shown in FIG. 22. In FIG. 19, “VC1” represents metal vias connected between M0CB and PO or between M0CB and MD, “VC2” represents metal vias connected between M0CA and PO or between M0CA and MD, “VC3” represents metal vias (there is only one shown in FIG. 19) connected between M0CB and M0CA, “V0” represents metal vias connected between M1 and M0CB or between M1 and M0CA, and “V1” represents metal vias connected between M2 and M1. Since there is no intermetal dielectric disposed between the first metal line layer and the second metal line layer, the metal vias VC3 may be thinner than metal vias VC1, VC2, V0, V1. In accordance with some embodiments, a thickness of a metal via VC3 may be the same as a thickness of an etch stop layer disposed between the first metal line layer and the second metal line layer (e.g., the etch stop layer 202 in FIG. 10). Similar to the configurations shown in FIGS. 13 and 15, the metal lines in the first metal line layer extend along the second axis D2, some of the metal lines in the second metal line layer extend along the second axis D2, and some of the metal lines in the second metal line layer extend along the third axis D3 for interconnection. In accordance with some embodiments, the first metal line layer may also include some metal lines extending along the third axis D3 for interconnection. In the illustrative embodiment, among the metal lines extending along the third axis D3 in the second metal line layer, some metal lines are spaced apart from and parallel to the source/drain contacts from the perspective of FIG. 19 (i.e., viewed from top or along the first axis D1), and some metal lines overlap one or more gate features along the first axis D1. In accordance with some embodiments, a spacing between any two of the metal lines that are adjacent along their widthwise direction in the first metal line layer is not smaller than a width of at least the narrowest one of the metal lines that extend in the same direction in the second metal line layer, and a spacing between any two of the metal lines that are adjacent along their widthwise direction and that extend along the second axis D2 in the second metal line layer is not smaller than a width of at least the narrowest one of the metal lines that extend in the same direction (e.g., along the second axis D2) in the first metal line layer. In accordance with some embodiments, a spacing between any two of the metal lines that are adjacent along their widthwise direction in the first metal line layer is not smaller than 1.5 times the width of at least the narrowest one of the metal lines that extend in the same direction in the second metal line layer, and a spacing between any two of the metal lines that are adjacent along their widthwise direction and that extend along the second axis D2 in the second metal line layer is not smaller than 1.5 times the width of at least the narrowest one of the metal lines that extend in the same direction (e.g., along the second axis D2) in the first metal line layer. In accordance with some embodiments, a spacing between any two of the metal lines that are adjacent along their widthwise direction in the first metal line layer is not smaller than twice the width of at least the narrowest one of the metal lines that extend in the same direction in the second metal line layer, and a spacing between any two of the metal lines that are adjacent along their widthwise direction and that extend along the second axis D2 in the second metal line layer is not smaller than twice the width of at least the narrowest one of the metal lines that extend in the same direction (e.g., along the second axis D2) in the first metal line layer. It can be seen from FIG. 20 that the cell includes twenty-one contact gate pitches, which means that this configuration leads to a smaller cell size in comparison to the configuration shown in FIG. 16, while the same logic function is achieved.

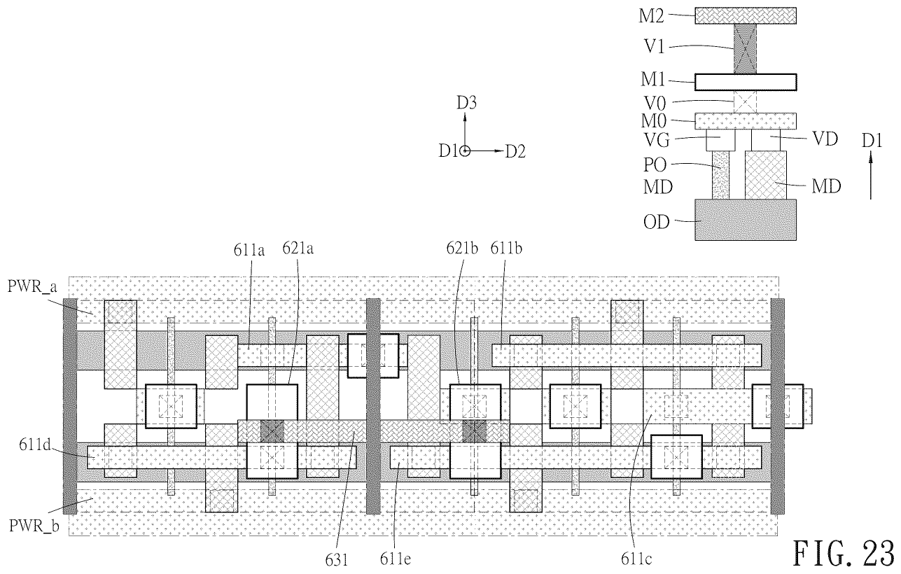

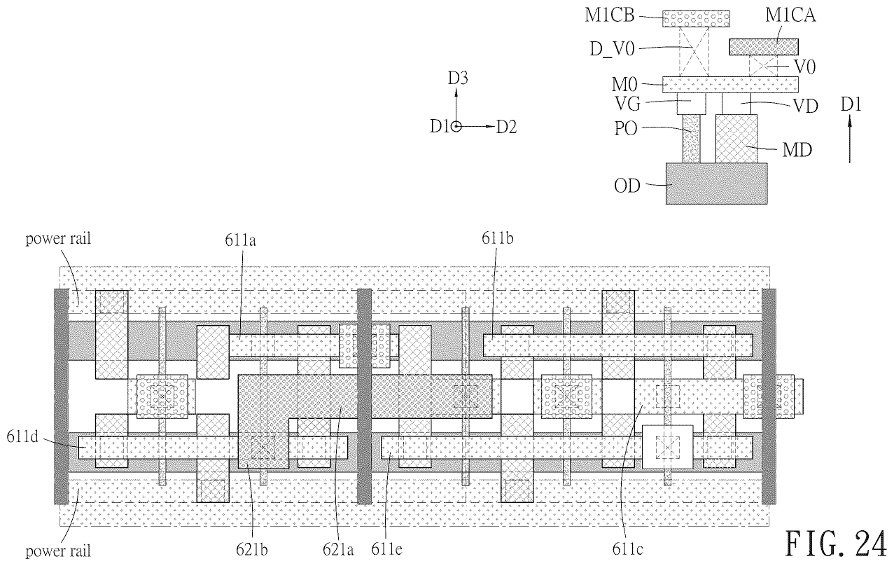

FIG. 23 illustrates a top view of a cell of an OR-AND-INVERT gate formed on a semiconductor substrate (e.g., the semiconductor substrate 100 in FIG. 8) in accordance with some embodiments, along with a diagram on the upper right side to illustrate various circuit features represented by various patterns and stacking relationships among the circuit features, where “OD” represents active regions, “MD” represents source/drain contacts, “PO” represents gate features, “M0” represents metal lines in a first metal line layer, “M1” represents metal lines in a second metal line layer, “M2” represents metal lines in a third metal line layer, “VG” represents metal vias connected between M0 and PO, “VD” represents metal vias connected between M0 and MD, “V0” represents metal vias connected between M1 and M0, and “V1” represents metal vias connected between M2 and M1. The metal lines in the first metal line layer (e.g., metal lines 611a, 611b, 611c, 611d, 611e) extend only in one direction (e.g., along the second axis D2 in FIG. 23) in a first intermetal dielectric (e.g., the intermetal dielectric 200 in FIG. 8), and the metal lines in the second metal line layer (e.g., a metal line 621a, 621b) extend only in another direction (e.g., along the third axis D3 in FIG. 23) in a second intermetal dielectric (e.g., the intermetal dielectric 213 in FIG. 8). The first metal line layer includes three rows of metal lines in a limited space between two power rails PWR_a, PWR_b, and the metal lines in different rows are connected through one or more metal lines that are disposed in another one or more metal line layers (e.g., the metal lines 621a, 621b are connected together through a metal line 631 that is disposed in the third metal line layer).

FIG. 24 illustrates a top view of a cell of an OR-AND-INVERT gate formed on a semiconductor substrate (e.g., the semiconductor substrate 100 in FIG. 10) in accordance with some embodiments, along with a diagram on the upper right side to illustrate various circuit features represented by various patterns and stacking relationships among the circuit features, where “OD” represents active regions, “MD” represents source/drain contacts, “PO” represents gate features, “M0” represents metal lines in a first metal line layer, “M1CA” represents metal lines in a second metal line layer, “M1CB” represents metal lines in a third metal line layer that is adjacent to the second metal line layer (i.e., there is no intermetal dielectric disposed between the second metal line layer and the third metal line layer), “VG” represents metal vias connected between M0 and PO, “VD” represents metal vias connected between M0 and MD, “V0” represents metal vias connected between M1CA and M0, and “D_V0” represents deep metal vias connected between M1CB and M0. The first metal line layer is disposed on the semiconductor substrate, and includes metal lines 611a, 611b, 611c, 611d, 611e extending along the second axis D2 in a first intermetal dielectric. The second metal line layer is disposed on the first metal line layer, and includes a metal line 621a extending along the second axis D2 in a second intermetal dielectric (e.g., the intermetal dielectric 200 in FIG. 10), and a metal line 621b extending along the third axis D3 in the second intermetal dielectric and overlapping a gate feature along the first axis D1. The third metal line layer is disposed on and adjacent to the second metal line layer along the first axis D1, and includes several metal pads in a third intermetal dielectric (e.g., the intermetal dielectric 210 in FIG. 10). From the perspective of FIG. 24 (i.e., viewed from top or along the first axis D1), the row of the metal lines 611a, 611b, the row of the metal lines 621a, 611c, and the row of the metal lines 611d, 611e are spaced apart from and parallel to each other along the third axis D3, and the metal line 621b is spaced apart from and parallel to all of the source/drain contacts. The cell of the OR-AND-INVERT gate illustrated in FIG. 24 has the same logic function as the cell of the OR-AND-INVERT gate illustrated in FIG. 23, with only an etch stop layer (e.g., the etch stop layer 202 in FIG. 10) being disposed between the second metal line layer (e.g., the layer of M1CA) and the third metal line layer (e.g., the layer of M1CB). As a result, a distance between the metal lines/pads in the second metal line layer and the metal lines/pads in the third metal line layer along the first axis D1 is smaller than a thickness of each of the first intermetal dielectric, the second intermetal dielectric, the third intermetal dielectric, and the metal lines in the first metal line layer, the second metal line layer and the third metal line layer, and is substantially equal to a thickness of the etch stop layer.

In accordance with some embodiments, an interconnect structure is disposed on a device region along a first axis, and includes a first dielectric layer, a second dielectric layer adjacent to the first dielectric layer along the first axis, a plurality of first metal lines disposed in the first dielectric layer and extending along a second axis transverse to the first axis, and a plurality of second metal lines disposed in the second dielectric layer and extending along the second axis. The second axis corresponds to a lengthwise direction of the plurality of first metal lines, and corresponds to a lengthwise direction of the plurality of second metal lines.

In accordance with some embodiments, the plurality of first metal lines and the plurality of second metal lines are parallel to each other when viewed along the first axis.

In accordance with some embodiments, the interconnect structure further includes a third metal line disposed in the second dielectric layer, connected to one of the plurality of second metal lines, and extending along a third axis transverse to the first axis and the second axis. The third axis corresponds to a lengthwise direction of the third metal line.

In accordance with some embodiments, the third metal line overlaps one of the plurality of first metal lines along the first axis.

In accordance with some embodiments, the third metal line is connected to another one of the plurality of second metal lines.

In accordance with some embodiments, the interconnect structure further includes a fourth metal line disposed in the first dielectric layer, connected to one of the plurality of first metal lines, and extending along the third axis. The fourth metal line is parallel to the third metal line when viewed along the first axis.

In accordance with some embodiments, the device region includes a plurality of transistors, each having a gate feature extending along the third axis, and a pair of source/drain contact features. The third metal line is spaced apart from the pair of source/drain contact features of each of the plurality of transistors when viewed along the first axis, and overlaps the gate feature of one of the plurality of transistors.

In accordance with some embodiments, a spacing between any two of the plurality of first metal lines that are adjacent along a third axis is greater than a width of one of the plurality of second metal lines, where the third axis is transverse to the first axis and the second axis.

In accordance with some embodiments, a spacing between any two of the plurality of second metal lines that are adjacent along the third axis is greater than a width of one of the plurality of first metal lines.

In accordance with some embodiments, the interconnect structure further includes a first conductive feature and a second conductive feature that are disposed at one side of the first dielectric layer along the first axis. One of the plurality of first metal lines is connected to the first conductive feature through a single via, and one of the plurality of second metal lines is connected to the second conductive feature through another single via.

In accordance with some embodiments, a distance between one of the plurality of first metal lines and one of the plurality of second metal lines along the first axis is smaller than a thickness of each of the first dielectric layer and the second dielectric layer.

In accordance with some embodiments, the interconnect structure further includes an etch stop layer disposed between the first dielectric layer and the second dielectric layer. A distance between one of the plurality of first metal lines and one of the plurality of second metal lines along the first axis is equal to a thickness of the etch stop layer.

In accordance with some embodiments, the device region includes a first device cell and a second device cell that have a same configuration. The plurality of second metal lines includes a first group of second metal lines overlapping the first device cell along the first axis, and a second group of second metal lines overlapping the second device cell along the first axis. An arrangement of the first group of second metal lines relative to the first device cell is same as an arrangement of the second group of second metal lines relative to the second device cell. The interconnect structure comprises a third metal line disposed in the second dielectric layer, extending along a third axis transverse to the first axis and the second axis, and interconnecting at least two of the plurality of second metal lines, one of which is in the first group of second metal lines, and another one of which is in the second group of second metal lines.

In accordance with some embodiments, a circuit structure includes a plurality of gate features and a plurality of source/drain features disposed in a semiconductor substrate, an interlayer dielectric disposed over the plurality of gate features and the plurality of source/drain features, a plurality of source/drain contacts disposed in the interlayer dielectric and electrically coupled to the plurality of source/drain features, a plurality of first metal lines disposed over the plurality of gate features and the plurality of source/drain contacts along a first axis, and a plurality of second metal lines disposed over the plurality of gate features and the plurality of source/drain contacts along the first axis. The plurality of first metal lines extend parallel to each other and along a second axis transverse to the first axis, and are distributed along a third axis transverse to the first axis and the second axis. The plurality of second metal lines are disposed over the plurality of gate features and the plurality of source/drain contacts along the first axis, are spaced apart from the plurality of first metal lines along the first axis by a distance smaller than a thickness of the plurality of second metal lines, and extend parallel to each other and along the second axis, and distributed along the third axis.

In accordance with some embodiments, the plurality of first metal lines and the plurality of second metal lines are parallel to each other when viewed along the first axis.

In accordance with some embodiments, a spacing between any two of the plurality of first metal lines that are adjacent along the third axis is greater than a width of one of the plurality of second metal lines. A spacing between any two of the plurality of second metal lines that are adjacent along the third axis is greater than a width of one of the plurality of first metal lines.

In accordance with some embodiments, the circuit structure further includes a third metal line connected to one of the plurality of second metal lines, and extending across one of the plurality of first metal lines along the third axis.

In accordance with some embodiments, the circuit structure further includes a first via that extends from one of the plurality of source/drain contacts to one of the plurality of first metal lines, and a second via that extends from another one of the plurality of source/drain contacts to one of the plurality of second metal lines.

In accordance with some embodiments, a method for fabricating an interconnect structure is provided. In one step, a first via is formed to be coupled to a first source/drain contact disposed in an interlayer dielectric. In one step, a first intermetal dielectric is formed to be disposed over the first via along a first axis, a first metal line is formed to be coupled to the first via and extends along a second axis in the first intermetal dielectric, and an etch stop layer is formed to be in contact with the first intermetal dielectric. The second axis is transverse to the first axis. In one step, a second via is formed to be coupled to a second source/drain contact disposed in the interlayer dielectric. The second via extends through the first intermetal dielectric and the etch stop layer. In one step, a second intermetal dielectric is formed to be in contact with the etch stop layer, and a second metal line is formed to be coupled to the second via and extends along the second axis in the second intermetal dielectric.

In accordance with some embodiments, in one step, a third metal line is formed to be coupled to the second metal line and extend along a third axis in the second intermetal dielectric. The third axis is transverse to the first axis and the second axis.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interconnect structure disposed on a device region along a first axis, comprising:
a first dielectric layer;
a second dielectric layer adjacent to the first dielectric layer along the first axis;
a plurality of first metal lines disposed in the first dielectric layer and extending along a second axis transverse to the first axis, wherein the second axis corresponds to a lengthwise direction of the plurality of first metal lines; and
a plurality of second metal lines disposed in the second dielectric layer and extending along the second axis, which corresponds to a lengthwise direction of the plurality of second metal lines.

2. The interconnect structure according to claim 1, wherein the plurality of first metal lines and the plurality of second metal lines are parallel to each other when viewed along the first axis.

3. The interconnect structure according to claim 2, further comprising a third metal line disposed in the second dielectric layer, connected to one of the plurality of second metal lines, and extending along a third axis transverse to the first axis and the second axis, wherein the third axis corresponds to a lengthwise direction of the third metal line.

4. The interconnect structure according to claim 3, wherein the third metal line overlaps one of the plurality of first metal lines along the first axis.

5. The interconnect structure according to claim 3, wherein the third metal line is connected to another one of the plurality of second metal lines.

6. The interconnect structure according to claim 3, further comprising a fourth metal line disposed in the first dielectric layer, connected to one of the plurality of first metal lines, and extending along the third axis, wherein the fourth metal line is parallel to the third metal line when viewed along the first axis.

7. The interconnect structure according to claim 3, wherein the device region includes a plurality of transistors, each having a gate feature extending along the third axis, and a pair of source/drain contact features, and
wherein the third metal line is spaced apart from the pair of source/drain contact features of each of the plurality of transistors when viewed along the first axis, and overlaps the gate feature of one of the plurality of transistors.

8. The interconnect structure according to claim 1, wherein a spacing between any two of the plurality of first metal lines that are adjacent along a third axis is greater than a width of one of the plurality of second metal lines, where the third axis is transverse to the first axis and the second axis.

9. The interconnect structure according to claim 8, wherein a spacing between any two of the plurality of second metal lines that are adjacent along the third axis is greater than a width of one of the plurality of first metal lines.

10. The interconnect structure according to claim 1, further comprising a first conductive feature and a second conductive feature that are disposed at one side of the first dielectric layer along the first axis,
wherein one of the plurality of first metal lines is connected to the first conductive feature through a single via, and one of the plurality of second metal lines is connected to the second conductive feature through another single via.

11. The interconnect structure according to claim 1, wherein a distance between one of the plurality of first metal lines and one of the plurality of second metal lines along the first axis is smaller than a thickness of each of the first dielectric layer and the second dielectric layer.

12. The interconnect structure according to claim 1, further comprising an etch stop layer disposed between the first dielectric layer and the second dielectric layer, wherein a distance between one of the plurality of first metal lines and one of the plurality of second metal lines along the first axis is equal to a thickness of the etch stop layer.

13. The interconnect structure according to claim 1, wherein the device region includes a first device cell and a second device cell that have a same configuration,
wherein the plurality of second metal lines includes a first group of second metal lines overlapping the first device cell along the first axis, and a second group of second metal lines overlapping the second device cell along the first axis,
wherein an arrangement of the first group of second metal lines relative to the first device cell is same as an arrangement of the second group of second metal lines relative to the second device cell, and
wherein the interconnect structure comprises a third metal line disposed in the second dielectric layer, extending along a third axis transverse to the first axis and the second axis, and interconnecting at least two of the plurality of second metal lines, one of which is in the first group of second metal lines, and another one of which is in the second group of second metal lines.

14. A circuit structure, comprising:
a plurality of gate features and a plurality of source/drain features disposed in a semiconductor substrate;
an interlayer dielectric disposed over the plurality of gate features and the plurality of source/drain features;
a plurality of source/drain contacts disposed in the interlayer dielectric and electrically coupled to the plurality of source/drain features;
a plurality of first metal lines disposed over the plurality of gate features and the plurality of source/drain contacts along a first axis, extending parallel to each other and along a second axis transverse to the first axis, and distributed along a third axis transverse to the first axis and the second axis; and
a plurality of second metal lines disposed over the plurality of gate features and the plurality of source/drain contacts along the first axis, spaced apart from the plurality of first metal lines along the first axis by a distance smaller than a thickness of the plurality of second metal lines, extending parallel to each other and along the second axis, and distributed along the third axis.

15. The circuit structure according to claim 14, wherein the plurality of first metal lines and the plurality of second metal lines are parallel to each other when viewed along the first axis.

16. The circuit structure according to claim 15, wherein a spacing between any two of the plurality of first metal lines that are adjacent along the third axis is greater than a width of one of the plurality of second metal lines, and
wherein a spacing between any two of the plurality of second metal lines that are adjacent along the third axis is greater than a width of one of the plurality of first metal lines.

17. The circuit structure according to claim 16, further comprising a third metal line connected to one of the plurality of second metal lines, and extending across one of the plurality of first metal lines along the third axis.

18. The circuit structure according to claim 14, further comprising a first via that extends from one of the plurality of source/drain contacts to one of the plurality of first metal lines, and a second via that extends from another one of the plurality of source/drain contacts to one of the plurality of second metal lines.

19. A method for fabricating an interconnect structure, comprising:
forming a first via that is coupled to a first source/drain contact disposed in an interlayer dielectric;
forming a first intermetal dielectric that is disposed over the first via along a first axis, a first metal line that is coupled to the first via and extends along a second axis in the first intermetal dielectric, and an etch stop layer that is in contact with the first intermetal dielectric, wherein the second axis is transverse to the first axis;
forming a second via that is coupled to a second source/drain contact disposed in the interlayer dielectric, the second via extending through the first intermetal dielectric and the etch stop layer; and
forming a second intermetal dielectric that is in contact with the etch stop layer, and a second metal line that is coupled to the second via and extends along the second axis in the second intermetal dielectric.

20. The method according to claim 19, further comprising: forming a third metal line that is coupled to the second metal line and extends along a third axis in the second intermetal dielectric, wherein the third axis is transverse to the first axis and the second axis.
